(19) United States
(12) Patent Application Publication
(10) Pub. No.: US 2025/0060664 A1
(43) Pub. Date: Feb. 20, 2025

(54) FORMULATIONS FOR FORMING A STRUCTURED NANOPARTICLE COMPOSITE

(71) Applicant: University of Massachusetts, Boston, MA (US)

(72) Inventors: James J. Watkins, South Hadley, MA (US); Vincent Einck, Vernon, VT (US); Daeeon Jung, Westborough, MA (US)

(21) Appl. No.: 18/721,049

(22) PCT Filed: Dec. 16, 2022
(86) PCT No.: PCT/US2022/081799

§ 371 Date: Jun. 17, 2024

Related U.S. Application Data
(60) Provisional application No. 63/265,603, filed on Dec. 17, 2021.

(51) Int. Cl. G03F 7/00; C08K 3/22; C09D 11/033; C09D 11/101

(52) U.S. Cl. CPC G03F 7/0002; C09D 11/033; C09D 11/101; G03F 7/0005; C08K 3/22; C08K 2003/2241; C08K 2201/003

(57) ABSTRACT

Structured nanoparticle composite and methods and formulations for forming the same. A formulation for forming a structured nanoparticle composite includes a nanoparticle with an average diameter of less than 50 nm. The formulation includes at least one solvent with a boiling point of 40° C. to 300° C. The formulation includes a binder for the nanoparticles that is the solvent or that has a different chemical structure than the solvent.

### CROSS-REFERENCE TO RELATED APPLICATION

This application claims the benefit of priority to U.S. Provisional Patent Application Ser. No. 63/265,603 filed Dec. 17, 2021, the disclosure of which is incorporated herein in its entirety by reference.

### STATEMENT OF GOVERNMENT SUPPORT

This invention was made with Government support under grant number 2122654 awarded by the National Science Foundation. The U.S. Government has certain rights in this invention.

### BACKGROUND

Nanoimprint lithography (NIL) is a commonly used technique for the patterning of polymers and metal oxides using direct contact. NIL is typically practiced via thermal embossing or with the use of UV curing to induce polymerization of imprint resists. The latter is typically called UV-assisted NIL or simply UV NIL. In UV-assisted NIL, the role of UV light is to initiate polymerization, often through the use of a photo-initiator for polymerization. UV initiated polymerization requires only modest doses of UV light so UV-NIL tools are typically equipped with low intensity UV sources either as broadband sources such as deuterium, mercury, halogen, fluorescent, incandescent or xenon lamps, or line band sources including LED arrays.

For soft conformal NIL, which can be practiced with or without a UV source, an elastomeric nanopatterned stamp is used for templating polymeric, composite nanoparticle (NP) imprint materials, composite nanocrystal (NC) imprint materials, or nanoparticle-based dispersion inks. However, due to the limitations on mobility of nanoparticles in nanoparticles-based dispersion inks, the one or more solvents in the ink must remain in the ink to a sufficient degree after the deposition of the ink to enable imprinting and capillary action filling of elastomeric stamp nanofeatures, but also must be easily removable after the imprinting.

### SUMMARY OF THE INVENTION

Various embodiments of the present invention provide a formulation for forming a structured nanoparticle composition. The formulation includes nanoparticles (such as, but not limited to, TiO₂ and/or ZrO₂) with an average diameter of less than 50 nm. The formulation also includes a binder for the nanoparticles, wherein the binder acts as a solvent and/or dispersant for the nanoparticles and has a boiling point of 40° C. to 300° C. The formulation optionally includes at least one solvent having a boiling point of 40° C. to 300° C. having a different chemical structure than the binder.

Various embodiments of the present invention provide a formulation for forming a structured nanoparticle composite. The formulation includes nanoparticles with an average diameter of less than 50 nm. The formulation includes at least one solvent with a boiling point of 40° C. to 300° C. The formulation also includes a binder for the nanoparticles that is a different compound from the at least one solvent with a boiling point of 40° C. to 300° C.

Various embodiments of the present invention provide a formulation for forming a structured nanoparticle composite. The formulation includes photocatalytic nanoparticles with an average diameter of less than 50 nm. The formulation includes a solvent with a boiling point of 40° C. to 200° C. The formulation also includes a binder for the nanoparticles that is a different compound than the solvent with a boiling point of 40° C. to 200° C., the binder including a precursor of a material of the nanoparticles, a metal oxide precursor, an insulating material, a transparent optical adhesive, a monomer, an alkoxide, an oligomer, a pre-polymer, a polymer, an organic polymer, a Si-containing polymer, a caged polymer, a branched polymer, a silane coupling agent, a silsesquioxane, or a combination thereof.

Various embodiments of the present invention provide a method of forming a structured nanoparticle composite. The method includes disposing an embodiment of the formulation described herein for forming the structured nanoparticle composite. The method includes patterning the formulation disposed on the substrate to produce structures including at least one dimension that is less than 2 microns. The method also includes photocatalytically oxidizing the patterned formulation to produce a patterned structure that is substantially free of organic material.

Various embodiments of the present invention provide a structured nanoparticle composite prepared from an embodiment of the formulation for forming a structured nanoparticle composite and/or using an embodiment of the method of forming a structured nanoparticle composite described herein.

In various embodiments, the formulation and method of the present invention increases the working lifetime of the film. Increasing the working lifetime of the film can allow for the use of higher quality materials in the NIL process, and can provide higher quality films that are more efficient to produce. In various embodiments, the formulation and method of the present invention can be used to produce structured nanoparticle composites that are high refractive index nanopatterned materials with diffraction patterns and that have applications in optical devices for augmented reality, virtual reality, and mixed reality, such as glasses, goggles, and heads-up displays (HUDs). In various embodiments, the structured nanoparticle composites can be binary gratings, slanted gratings, or blazed gratings. Nanostructured optical elements can be organized to make focusing devices such as metalenses. In some embodiments, the optical elements are organized radially. Lens applications can range from consumer markets in the form of camera lenses to aerospace and defense markets due to the high thermal and mechanical stability of various embodiments of the structured nanoparticle composition. The method of forming the structured nanoparticle composite can be applicable to 3D sensors, structured light sensors, and LIDAR. The solvent engineering technique of the present invention can be utilized to allow for the manufacturing of the structured nanoparticle composite in a short time and at a lower cost relative to etch-based products.

### BRIEF DESCRIPTION OF THE FIGURES

The drawings illustrate generally, by way of example, but not by way of limitation, various embodiments of the present invention.

FIG. 1 illustrates solvents suitable for a multicomponent solvent system including two low boiling solvents (PGMEA and EL) and one high boiling solvent (BEEA), in accordance with various embodiments.

FIGS. 2A-2B illustrate photos of spin-coated films on 150 mm Si wafers from D1.1 (FIG. 2A) and V3.3 (FIG. 2B) formulations, showing the scalability of the process on a larger scale with a multicomponent solvent system having a heavier solvent, BEEA, in accordance with various embodiments.

FIGS. 3A-3B illustrate refractive index (RI) curves of the films prepared from D1.1 formulation fitted with the ideal Cauchy model (FIG. 3A) and its graded model (FIG. 3B), in accordance with various embodiments.

FIG. 4 illustrates UV-vis transmittance of the films from D1.1 formulation fabricated on 150 mm fused silica substrates, ratioed by a bare substrate, in accordance with various embodiments.

FIGS. 5A-5C illustrate 2D (FIG. 5A) and 3D (FIG. 5B) AFM images of the film prepared from D1.1 formulation and a height profile (FIG. 5C) extracted from the line cut in the 2D image, in accordance with various embodiments.

FIGS. 6A-6B illustrates NMR spectra for nanoparticle solution before (FIG. 6A) and after (FIG. 6B) UV irradiation. The peak broadening and appearance of new, well resolved peaks, indicates the decomposition of the solvent into new species, in accordance with various embodiments.

FIGS. 7A-7D illustrates photographs of TiO₂-based inks showing differences before and after 15,000 repetitions of pulsed UV. The D1.1 formulation (FIG. 7A) contains three different solvents, PGMEA, EL, and BEEA prior to UV exposure, with photographs after exposure to UV shown in FIG. 7B (PGMEA), FIG. 7C (PGMEA and EL), and FIG. 7D (PGMEA and BEEA), in accordance with various embodiments.

FIGS. 8A-8C illustrate NMR spectra of three different TiO₂-based inks with different combinations of solvents without any binder or surfactant added after 15,000 repetitions of pulsed UV, with the solvent of FIG. 8A being PGMEA, the solvent of FIG. 8B being PGMEA and EL, and with the solvent of FIG. 8C being PGMEA and BEEA, in accordance with various embodiments.

FIG. 9 illustrates IR spectra of titania composite films with increasing UV treatment and the decrease of organic carbonyl and aliphatic peaks as organic materials are decomposed in the film to assist with the cure, release of oxidizable organics and densification of the structure, in accordance with various embodiments.

FIGS. 10A-10F illustrate 2D hetero-region synchronous (a,b,c) and asynchronous (d,e,f) correlation spectra in the regions of v(—CH₂—)/v(C═O), v(—CH₂—)/v(—Si—O—), and v(C═O)/v(—Si—O—) in the course of increasing the number of UV pulses from 0 (as-deposited before UV) to 20,000, in accordance with various embodiments.

FIG. 11A illustrates a method of forming a structured nanoparticle composite, with the left image showing elastomeric stamps that include hard and soft PDMS, the middle image showing the imprinting of the stamps on a spin-coated film of the D1.1 formulation on wafers, and with the right image showing the imprinted films on the wafers with the stamps removed.

FIG. 11B illustrates optical images (the three left-most images) and corresponding scanning electron microscopy (SEM) images (the four images to the right of each optical image) of visible wavelength (543 nm) metalenses imprinted using a three-component solvent system (D1.1) with high and low boiling point solvents, proving high fidelity pattern replication on large wafers using extended processing times, in accordance with various embodiments. The imprinted metalens patterns were replicated using an imprint mastering technique, not directly replicated from the original master mold.

FIGS. 12A-12F illustrate SEM images of another visible wavelength (543 nm) metalens imprinted using a three-component solvent system (D1.1) with high and low boiling point solvents, with FIGS. 12A-B illustrating a TiO₂ particle size of 10 nm, and with FIGS. 12C-F illustrating a TiO₂ particle size of 20 nm, in accordance with various embodiments.

FIGS. 13A-13F illustrate scanning electron microscopy images of visible wavelength waveguides including visible wavelength pitch optical gratings, imprinted using a three-component solvent system (D1.1) with high and low boiling point solvents, in accordance with various embodiments.

FIG. 14 illustrates cross sectional scanning electron microscopy images of infrared wavelength waveguides including infrared wavelength pitch optical gratings, imprinted using a three-component solvent system (D1.1) with high and low boiling point solvents, in accordance with various embodiments.

FIGS. 15A-15D illustrates scanning electron microscopy images of infrared wavelength waveguides including infrared wavelength pitch optical gratings, imprinted using a three-component solvent system (D1.1) with high and low boiling point solvents, showing successful large area patterning, in accordance with various embodiments.

FIGS. 16A-16F illustrates scanning electron microscopy images of infrared wavelength waveguides including infrared wavelength pitch optical gratings, imprinted using a three-component solvent system (D1.1) with high and low boiling point solvents, in accordance with various embodiments.

### DETAILED DESCRIPTION OF THE INVENTION

Reference will now be made in detail to certain embodiments of the disclosed subject matter. While the disclosed subject matter will be described in conjunction with the enumerated claims, it will be understood that the exemplified subject matter is not intended to limit the claims to the disclosed subject matter.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise.

In this document, the terms “a,” “an,” or “the” are used to include one or more than one unless the context clearly dictates otherwise. The term “or” is used to refer to a nonexclusive “or” unless otherwise indicated. The statement “at least one of A and B” or “at least one of A or B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section.

In the methods described herein, the acts can be carried out in any order without departing from the principles of the invention, except when a temporal or operational sequence is explicitly recited. Furthermore, specified acts can be carried out concurrently unless explicit claim language recites that they be carried out separately. For example, a claimed act of doing X and a claimed act of doing Y can be conducted simultaneously within a single operation, and the resulting process will fall within the literal scope of the claimed process.

The term “about” as used herein can allow for a degree of variability in a value or range, for example, within 10%, within 5%, or within 1% of a stated value or of a stated limit of a range, and includes the exact stated value or range.

The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%. The term “substantially free of” as used herein can mean having none or having a trivial amount of, such that the amount of material present does not affect the material properties of the composition including the material, such that about 0 wt % to about 5 wt % of the composition is the material, or about 0 wt % to about 1 wt %, or about 5 wt % or less, or less than, equal to, or greater than about 4.5 wt %, 4, 3.5, 3, 2.5, 2, 1.5, 1, 0.9, 0.8, 0.7, 0.6, 0.5, 0.4, 0.3, 0.2, 0.1, 0.01, or about 0.001 wt % or less, or about 0 wt %.

As used herein, the term “polymer” refers to a molecule having at least one repeating unit and can include copolymers.

Composite and NP dispersion imprint materials provide advantages over polymers in optics for their significantly higher refractive index, enabling a wider field of view. NP dispersion inks enable structures with high thermal and oxidative stability, extending device lifetime and high-end applications. Due to the limitations on mobility attributed hard sphere packing or other geometric packing arrangements in dry nanoparticles inks, solvents are required for ink deposition on the substrate as well as to enable imprinting and capillary action filling of the elastomeric stamp nanofeatures. Boiling point regimes are chosen to match the required spin coating conditions as well as to match process time requirements for automated manufacturing nanoimprinting tools, such as an AutoSCIL 150, EVG 720, EVG 7200, EVG 7300, or Canon FPA-1200. For success on full scale wafers, multicomponent solvent blends of high and low boiling point enable stability of the film for transferring to an imprint module. The higher boiling point secondary solvent stays present in the film after spin coting and enables the uniform film to maintain a viscosity regime suitable for imprinting for an extended period of time, enabling wider processing window for nanoparticle composites. The presence of a secondary solvent with high boiling point provides a more uniform spread of the composite ink over a larger wafer during the spin coating compared to a simple mixture of low boiling solvents. Although the high boiling point solvents are more difficult to remove from the imprinted structure, upon intense UV curing/exposure photooxidation catalyzed by the nanoparticles (e.g, titania NPs) leads to the degradation and removal of the residual solvents from the composite, enabling densification further by breaking down the solvent into smaller parts that can be transported through the small interstitial pores in the imprint more rapidly than the parent solvent molecules and can also diffuse more rapidly into the stamps.

While surface tension, surface energy and substrate choice play a key role in solvent selection, the low boiling point component range can be 100° C. to 200° C. and the high boiling point component range can be from 170° C. to 300° C. Two or more components may be needed to maximize formulation stability, lifetime, and safety. A binder for the nanoparticles can act as a solvent and/or dispersant for the nanoparticles, such as a low boiling point solvent and/or dispersant and/or a high boiling point solvent and/or dispersant. In various embodiments, the binder can be substantially non-volatile; e.g., the decomposition temperature of the binder can be less than its boiling point. In various embodiments, the binder can be inert during formation of the structured nanoparticle composite. In various embodiments, the binder can undergo a chemical reaction during processing. The product of such reaction can remain in the formed structured nanoparticle composite, or the one or more products of such reaction can be partially or substantially completely removed to obtain a structured nanoparticle that is partially or substantially free of the one or more products.

The use of polymer and organic containing composites raise concerns about device lifetime due to oxidation of the organic material during use of the device and the resulting device and material stabilities. The Working Examples are intended to illustrate a formulation technique by which utilizing the photooxidative chemistry of titanium dioxide, organics can be decomposed and removed from the imprint material using high intensity UV exposure. It is important to note such an approach is different from traditional UV NIL where the purpose of the UV exposure is to induce polymerization of a chemical conversion to form a robust pattern structured in which the polymerized or converted materials remain present. In the embodiments described herein, much higher intensities of UV light are used to degrade and ultimately remove organics from the film. In some embodiments, the resulting patterned structure is substantially free of organic material after high intensity UV exposure. In some embodiments, a low intensity UV dose can be followed by a high intensity UV dose. In some embodiments, a low intensity UV dose can be used in the presence of the mold or the master and a high intensity UV dose can be used after removal of the mold or master. In some embodiments, catalytic nanoparticles such as TiO₂ are used as photocatalysts to aid in the degradation and removal of the organic materials from the film. One distinction between this work and the prior art in NIL is the use of UV exposure in a destructive fashion to remove materials from patterned structure. In some embodiments, photoinitiators can be added to enhance the photocatalytic activity of catalytic nanoparticles and to aid in the crosslinking of the components and in the degradation and removal of the organic materials from the film. In some embodiments, a post-imprint processing including calcination, UV-Ozone, O₂-plasma, or a combination thereof can be used after UV dose and removal of the mold or master to make the resulting patterned structure completely free of organic material.

Organic species originate as solvent, ligands, and components of the binder, but upon UV irradiation, IR and NMR have confirmed the decomposition of the organic species both in film and solution. The decomposition of the organics facilitates their release from the titanium dioxide nanocrystal composite matrix to afford an inorganic matrix that exhibits self-cleaning behavior as documented in the literature (e.g., via generation of titania radicals).

While depositing and imprinting a nanoparticle composite, formulation of the nanoparticle composite solution requires selecting a solvent mixture to provide a viscosity regime suitable for imprinting over a certain time interval. Such circumstances can include: processes that require a time interval for transferring the assembly of the substrate and spin coated film to a separate module for imprinting or curing; processes by which the sample must propagate down a web or manufacturing line; patterning techniques by which the solution viscosity or cure are used in following steps such as liquid transfer lithography or screen printing; patterning on substrates with high or low surface energies, requiring tuning of the drying rate to match wetting duration; or a combination thereof.

As one example, we have developed a process by which crystalline nanoparticles can be patterned directly using NIL and a pulsed UV curing mechanism. The process uses the chemical mechanism of the conversion of UV light to radical titanol species, which enables covalent inorganic bonding in the imprint material, but additionally decomposes and drives the solvent and decomposed products out of the matrix by local thermal gradient caused by the absorption of UV within the titania nanocrystals. The solidification of the cure can be witnessed by the ability to fabricate high aspect ratio (>8) nanopillars and the ability to produce 10 or more imprints from a single elastomeric PDMS-based stamp.

The mechanism of the cure includes free radical chemistry which enables many reactions to occur in parallel and in series. Two main regimes are critical to the cure: the first is the decomposition of organic species to radical species and setting up the inorganic network and the second is the sintering of the inorganic matrix. In the first stage, the imprint is done, making an initial inorganic network between nanoparticles that works as a template for the conversion to an all-inorganic structure. During this process the solvents are both expelled due to the heated surface of the titania nanoparticles under the exposure of UV and decomposed by the titania radicals that interact with organic linkages/functional groups of the solvents, ligand, and binder such as ester and ether groups by oxidation. In the second step, the stamp is removed, and extended UV in the second step after the stamp removal can be selectively used in some cases. The stamp can be removed before the long UV exposure once the imprinted nanofeatures are mechanically robust enough to be demolded from the stamp to avoid any undesired excessive degradation of the stamp by UV, which can help extend the lifetime of the stamp and improve the productivity of the whole process. The extended UV removes residual organic materials in the matrix and convert carbonyls and aliphatic groups from the characterization spectra. This is a use case where the decomposition of the solvent assists in the fabrication of the inorganic matrix in an inorganic nanocrystal composite.

In routes to increasing the substrate area, the longer coating times required for consistent coverage without inducing shear aggregation prevent the deposition of a film for imprinting. While utilizing a single low boiling point formulation works well on small samples, scaling the process to large wafers requires an additional component to the formulation in the form of a heavy solvent to maintain the film fluidity throughout coating and imprinting. Further formulation with BEEA, a higher BP solvent, increased the working time by 10× without compromising imprintability on 150 mm diameter and larger wafers. This is one use case where tailoring the solvent content allows for tuning of the formulation to the tooling for manufacturing.

### Formulation for Forming a Structured Nanoparticle Composite.

Various embodiments of the present invention provide a formulation for forming a structured nanoparticle composite. The formulation includes nanoparticles with an average diameter of less than 50 nm. The average diameter can be a volume average diameter. The average diameter of the nanoparticles can be obtained using dynamic light scattering, electron microscopy, commercial particle size analysis tools from Zygo, Malvern, and other manufacturers, or other suitable techniques. The formulation can include at least one solvent with a boiling point of 40° C. to 300° C. The formulation can additionally or alternatively include at least one solvent with a boiling point of 40° C. to 500° C. The formulation also includes a binder for the nanoparticles, which can also serve as a solvent or dispersant. The binder can be a separate component from the at least one solvent and have a different chemical structure. In other aspects, the binder is the same component as the at least one solvent.

The nanoparticles can be any suitable nanoparticles. The nanoparticles can have an average diameter of 1 nm to less than 50 nm (e.g., volume-average), or less than 50 nm and greater than or equal to 1 nm, 2, 3, 4, 5, 6, 7, 8, 9, 10, 12, 14, 16, 18, 20, 22, 24, 26, 28, 30, 32, 34, 36, 38, 40, 42, 44, 46, 48, or 49 nm. The formulation can include ligands bound to the nanoparticles. The compound can include functional groups bounded to the nanoparticles. The nanoparticles can include a metal oxide; the nanoparticles can be metal oxide nanoparticles. The nanoparticles can include TiO₂, ZrO₂, HfO₂, ZnO, or a combination thereof.

The formulation can have any suitable weight ratio of the solvent to the nanoparticles to the binder, such as (1-90):(10-90):(1-20), (1-80):(20-85):(1-15), (50-80):(10-30):(1-10), such as 74:21:5. The formulation can have any suitable weight ratio of the nanoparticles to the binder, such as (70-95):(5-30), or (80-90):(10-20), such as 85:15.

The at least one solvent with a boiling point of 40° C. to 300° C., and/or a binder having a boiling point of 40° C. to 300° C., can include an ether functional group, an ester, acetate, ketone, methylene, ethylene, propylene, propylene oxide, ethylene oxide, methoxy, ethoxy, isopropoxy, hydroxyl, carboxylic acid, anhydride, urea, carbonate, silane, siloxane, acrylate, methacrylate, vinyl, hydride, phenyl, or a combination thereof. The at least one solvent with a boiling point of 40° C. to 300° C., and/or a binder having a boiling point of 40° C. to 300° C., can be an ether, ester, acetate, ketone, methylene, ethylene, propylene, propylene oxide, ethylene oxide, methoxy, ethoxy, isopropoxy, hydroxyl, carboxylic acid, anhydride, urea, carbonate, silane, siloxane, acrylate, methacrylate, vinyl, hydride, phenyl, or a combination thereof.

The at least one solvent with a boiling point of 40° C. to 300° C. can include one solvent (e.g., and no more than one solvent), or the at least one solvent can include one more than one solvent (e.g., two solvents, three solvents, or more). The at least one solvent having a boiling point of 40° C. to 300° C. can have a boiling point of 40° C. to 200° C., 100° C. to 200° C., 170° C. to 300° C., or less than or equal to 300° C. and greater than or equal to 40° C., 50, 60, 70, 80, 90, 100, 110, 120, 130, 140, 150, 160, 170, 180, 190, 200, 210, 220, 230, 240, 250, 260, 270, 280, or 290° C.

In some embodiments, the at least one solvent with a boiling point of 40° C. to 300° C. can include two solvents (e.g., two solvents plus any one or more additional solvents, or two solvents and no more than two solvents). The at least one solvent can includes a solvent with a boiling point of 100° C. to 200° C. (e.g., less than or equal to 200° C. and greater than or equal to 100° C., 105, 110, 115, 120, 125, 130, 135, 140, 145, 150, 155, 160, 165, 170, 175, 180, 185, 190, or 195° C.) and a solvent with a boiling point of 170° C. to 300° C. (e.g., less than or equal to 300° C. and greater than or equal to 170° C., 175, 180, 185, 190, 195, 200, 205, 210, 215, 220, 225, 230, 235, 240, 245, 250, 255, 260, 265, 270, 275, 280, 285, 290, or 295° C.).

The solvent with a boiling point of 100° C. to 200° C., and/or a binder having a boiling point of 100° C. to 200° C., can include an ether functional group, an ester, acetate, ketone, methylene, ethylene, propylene, propylene oxide, ethylene oxide, methoxy, ethoxy, isopropoxy, hydroxyl, carboxylic acid, anhydride, urea, carbonate, silane, siloxane, acrylate, methacrylate, vinyl, hydride, phenyl, or a combination thereof. The solvent with a boiling point of 100° C. to 200° C., and/or a binder having a boiling point of 100° C. to 200° C., can be an ether, ester, acetate, ketone, methylene, ethylene, propylene, propylene oxide, ethylene oxide, methoxy, ethoxy, isopropoxy, hydroxyl, carboxylic acid, anhydride, urea, carbonate, silane, siloxane, acrylate, methacrylate, vinyl, hydride, phenyl, or a combination thereof. The solvent with a boiling point of 100° C. to 200° C., and/or a binder having a boiling point of 100° C. to 200° C., can be degradable by photooxidation.

The solvent with a boiling point of 170° C. to 300° C., and/or a binder having a boiling point of 170° C. to 300° C., can include an ether functional group, an ester, acetate, ketone, methylene, ethylene, propylene, propylene oxide, ethylene oxide, methoxy, ethoxy, isopropoxy, hydroxyl, carboxylic acid, anhydride, urea, carbonate, silane, siloxane, acrylate, methacrylate, vinyl, hydride, phenyl, or a combination thereof. The solvent with a boiling point of 170° C. to 300° C., and/or a binder having a boiling point of 170° C. to 300° C., can be an ether, ester, acetate, ketone, methylene, ethylene, propylene, propylene oxide, ethylene oxide, methoxy, ethoxy, isopropoxy, hydroxyl, carboxylic acid, anhydride, urea, carbonate, silane, siloxane, acrylate, methacrylate, vinyl, hydride, phenyl, or a combination thereof. The solvent with a boiling point of 170° C. to 300° C., and/or a binder having a boiling point of 170° C. to 300° C., can be degradable by photooxidation.

The nanoparticles can be catalytic. The nanoparticles can be photocatalytic. The nanoparticles can be catalytic for photooxidation of the at least one solvent in the formulation with a boiling point of 40° C. to 300° C., and/or for photooxidation of a binder in the formulation with a boiling point of 40° C. to 300° C. The nanoparticles can be catalytic for photooxidation of the at least one solvent with a boiling point of 40° C. to 300° C. upon exposure to UV light, and/or for photooxidation of a binder with a boiling point of 40° C. to 300° C. upon exposure to UV light. The nanoparticles can be catalytic for photooxidation of the solvent with boiling point of 100° C. to 200° C., and or for photooxidation of a binder with a boiling point of 100° C. to 200° C. The nanoparticles can be catalytic for photooxidation of the solvent with boiling point of 170° C. to 300° C., and/or for photooxidation of a binder with a boiling point of 170° C. to 300° C. The nanoparticles can be catalytic for photooxidation of the solvent with boiling point of 100° C. to 200° C. upon exposure to UV light, and/or for photooxidation of a binder with a boiling point of 100° C. to 200° C. upon exposure to UV light. The nanoparticles can be catalytic for photooxidation of the solvent with boiling point of 170° C. to 300° C. upon exposure to UV light, and/or for photooxidation of a binder with a boiling point of 170° C. to 300° C. upon exposure to UV light. The nanoparticles can be catalytic for photooxidation of ligands bound to the surface of the nanoparticles. The nanoparticles can be catalytic for photooxidation of the binder.

The binder can be any suitable one or more binders. The binder can include a precursor of a material of the nanoparticles, a metal oxide precursor, an insulating material, a transparent optical adhesive, a monomer, an alkoxide, an oligomer, a pre-polymer, a polymer, an organic polymer, a Si-containing polymer, a caged polymer, a branched polymer, a silane coupling agent, a silsesquioxane, or a combination thereof.

The formulation can optionally include one or more surfactants. The surfactant can include a polymer architecture ranging from linear, branched, hyperbranched, brush-block, star, or network polymers including one or more domains including ionic, anionic, polyelectrolyte, fluorinated, hydrophobic, and/or hydroscopic. A surfactant can include a head group that is charged or neutral and/or a tail that includes a charged or neutral functional group.

### Method of Forming a Structured Nanoparticle Composite.

Various embodiments of the present invention provide a method of forming a structured nanoparticle composite. The method can be any suitable method that forms a structured nanoparticle composite from the formulation for forming a structured nanoparticle composite described herein. The method can include disposing an embodiment of the formulation described herein for forming a structured nanoparticle composite on a substrate. The method can include patterning the formulation disclosed on the substrate to provide structure including at least one dimension that is less than 2 microns. The method can also include photocatalytically oxidizing the patterned formulation to produce a patterned structure that is substantially free of organic material.

The photocatalytic oxidation can degrade organic materials in the patterned formulation that include but are not limited to solvents, ligands bound to nanoparticles, binders, stabilizers, or a combination thereof. The organic materials degraded in the patterned formulation can include a solvent, a ligand, a ligand bound to a nanoparticle, a binder, stabilizer, a surfactant, or a combination thereof.

The photocatalytic oxidation can be performed in any suitable way. The photocatalytic oxidation can include using UV light. The photocatalytic oxidation can include using pulsed UV light. The photocatalytic oxidation can include using UV light with a minimum intensity of 5 mW/cm², such as wherein the UV light or pulsed UV light has an intensity of 5 mW/cm² or more, or equal to or greater than 10 mW/cm², 15, 20, 25, 50, 100, 150, 200, 250, 500, 750, or 1,000 mW/cm² or more. The photocatalytic oxidation can include using light having at least one wavelength that is 100 nm to 450 nm, or 300 nm to 400 nm, or 350 nm to 380 nm, or 365 nm, or less than or equal to 450 nm and greater than or equal to 100 nm, 125, 150, 175, 200, 225, 250, 275, 300, 310, 320, 330, 340, 350, 355, 360, 361, 362, 363, 364, 365, 366, 367, 368, 369, 370, 375, 380, 390, 400, 410, 420, 430, or 440 nm. The photocatalytic oxidation can include using pulsed UV light including 1,000 to 20,000 pulse repetitions, such as less than or equal to 20,000 pulse repetitions and greater than or equal to 1,000, 2,000, 5,000, 7,500, 10,000, 12,500, 15,000, 17,500, or 19,000 pulse repetitions. The photocatalytic oxidation can include using UV light generating with a light emitting diode (LED). The photocatalytic oxidation can include using light generated using a flash lamp or a broadband light source.

### Structured Nanoparticle Composite.

Various embodiments of the present invention provide a structured nanoparticle composite. The structured nanoparticle composite can be any suitable structured nanoparticle composite prepared from the formulation described herein for forming a structured nanoparticle composite and/or from the method described herein for forming a structure nanoparticle composite.

The structured nanoparticle composite can be optically transparent at one or more wavelengths. The structured nanoparticle composite can include features with at least one dimension smaller than 1 micron. The structured nanoparticle composite can be arranged (e.g., the features on the structured nanoparticle composite with at least one dimension smaller than 1 micron can be arranged/patterned) to manipulate electromagnetic radiation, manipulated visible light, manipulate infrared light, or a combination thereof. The structured nanoparticle composite can include or can be an optical grating. The structured nanoparticle composite can include or can be a metalens or a holographic component. The structured nanoparticle composite can be a component included in a 3D sensor.

The pattern on the structured nanoparticle composite formed via the patterning during the method of making the structured nanoparticle composite can include features having one dimension that is less than 2 microns. The dimension can be height, width, and/or length of the features, and can have a size of 0.001 microns to less than 2 microns, or less than 2 microns and greater than or equal to 0.001 microns, 0.002, 0.005, 0.01, 0.02, 0.03, 0.04, 0.05, 0.06, 0.07, 0.08, 0.09, 0.1, 0.15, 0.2, 0.25, 0.3, 0.35, 0.4, 0.45, 0.5, 0.55, 0.6, 0.65, 0.7, 0.75, 0.8, 0.85, 0.9, 1, 1.05, 1.10, 1.15, 1.2, 1.25, 1.3, 1.35, 1.4, 1.45, 1.5, 1.55, 1.6, 1.65, 1.7, 1.75, 1.8, 1.85, 1.9, or 1.95 microns.

The pattern on the structured nanoparticle composite formed via the patterning during the method of making the structured nanoparticle composite can include features having any suitable height:width aspect ratio, such as from about 0.5:1 to about 10:1, about 1.5:1 to about 10:1, about 2:1 to about 10:1, about 3:1 to 10:1, about 4:1 to about 10:1, about 5:1 to about 10:1 about 6:1 to about 10:1, about 7:1 to about 10:1, about 9:1 to about 10:1, or any range or sub-range between these values. In some embodiments, the features can have a height:width aspect ratio of about 2:1, about 3:1, about 4:1, about 5:1, about 6:1, about 7:1, about 8:1, about 9:1, about 10:1, about 15:1, or any range or sub-range between these values. The features can include nanostructures slanted from an angle of zero (binary) to 45° or have a combination of slanted and binary features.

The height of a feature can be from about 0.05 microns to about 30 microns, about 0.5 microns to about 25 microns, about 1 micron to about 22 microns, about 2 microns to about 20 microns, about 3 microns to about 18 microns, about 4 microns to about 16 microns, about 5 microns to about 14 microns, about 6 microns to about 12 microns, or any range or sub-range in between these values. The height of a feature can be about 0.05 microns, 1 microns, about 2 microns, about 3 microns, about 4 microns, about 5 microns, about 6 microns, about 7 microns, about 8 microns, about 9 microns, about 10 microns, about 11 microns, about 12 microns, about 13 microns, about 14 microns, about 15 microns, about 16 microns, about 17 microns, about 18 microns, about 19 microns, about 20 microns, about 21 microns, about 22 microns, about 23 microns, about 24 microns, about 25 microns, or any range or sub-range in between these values.

The width of a feature can be from about 0.03 microns to about 30 microns, about 0.5 microns to about 25 microns, about 1 micron to about 22 microns, about 2 microns to about 20 microns, about 3 microns to about 18 microns, about 4 microns to about 16 microns, about 5 microns to about 14 microns, about 6 microns to about 12 microns, or any range or sub-range in between these values. The width of a feature can be about 0.03 microns to about 1 microns, about 2 microns, about 3 microns, about 4 microns, about 5 microns, about 6 microns, about 7 microns, about 8 microns, about 9 microns, about 10 microns, about 11 microns, about 12 microns, about 13 microns, about 14 microns, about 15 microns, about 16 microns, about 17 microns, about 18 microns, about 19 microns, about 20 microns, about 21 microns, about 22 microns, about 23 microns, about 24 microns, about 25 microns, or any range or sub-range in between these values.

In some embodiments, the features are arranged in a periodic pattern. In some embodiments, the features are randomly arranged. In some embodiments, the features are arranged in a non-periodic pattern. In some embodiments, the features on the mold can be arranged such that portions of the mold have a high areal density of features spaced closely together and another portion of the mold with a pattern that does not contain any features or contains relatively few features that are spaced far apart relative to the feature size.

In some embodiments, the separation between any two features can be from about 0.03 microns to about 1000 microns, about 5 microns to about 900 microns, about 10 microns to about 800 microns, about 20 microns to about 700 microns, about 50 microns to about 600 microns, about 75 microns to about 500 microns, about 100 microns to about 400 microns, or any range or sub-range in between these values. The separation between any two features can be about 0.03 microns, about 1 micron, about 5 microns, about 10 microns, about 15 microns, about 25 microns, about 35 microns, about 45 microns, about 55 microns, about 65 microns, about 75 microns, about 85 microns, about 95 microns, about 105 microns, about 115 microns, about 125 microns, about 135 microns, about 145 microns, about 155 microns, about 165 microns, about 175 microns, about 185 microns, about 195 microns, about 205 microns, about 215 microns, about 225 microns, about 235 microns, about 245 microns, about 255 microns, about 265 microns, about 275 microns, about 285 microns, about 295 microns, about 305 microns, about 315 microns, about 325 microns, about 335 microns, about 345 microns, about 355 microns, about 365 microns, about 375 microns, about 385 microns, about 395 microns, about 405 microns, about 415 microns, about 425 microns, about 435 microns, about 445 microns, about 455 microns, about 465 microns, about 475 microns, about 485 microns, about 495 microns, or any range or sub-range between these values.

### Examples

Various embodiments of the present invention can be better understood by reference to the following Examples which are offered by way of illustration. The present invention is not limited to the Examples given herein.

Unlike polymeric matrix-based composites where polymers or monomers act as the viscosity determining component, pure inorganic composites require solvents to imprint a pattern by maintaining a transient viscosity. Their organic contents also need to be removed from the final structure. Hence, the selection and quantity of the solvents for the titania-based ink are important and can be engineered such that they yield a proper viscosity regime and decompose under the UV conditions for curing the structure and sintering. Additionally, some combinations of solvents, particularly a mixture of high and low boiling point solvents, allow for longer process windows and enable the use larger area wafer and panels, which enables more reliable manufacturing and higher throughput on commercial scale tools. For optical applications, it is critical that nanoparticles remain sub 50 nm to avoid a haze limiting regime, all nanoparticles use in this work from Pixelligent are <20 nm diameter. Additionally, nanoparticles are covalently ligated to increase stability at high concentrations, requiring the degradation of the ligands in addition to solvents to access the nanoparticle surface and to eliminate the organic content.

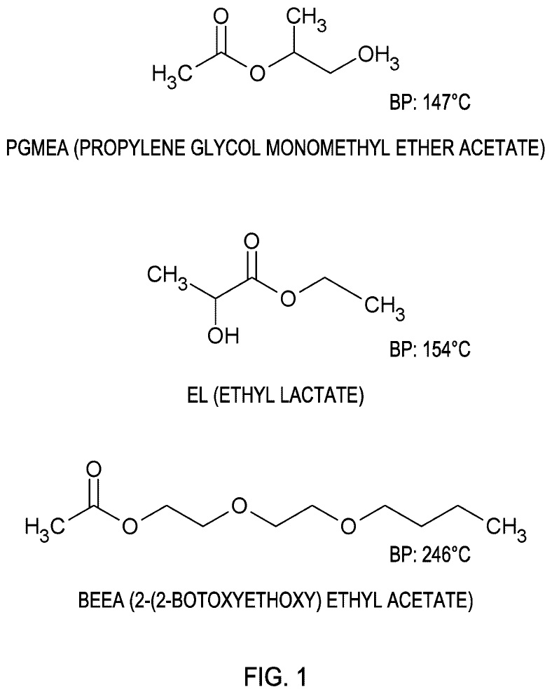

The three primary solvents in this study are presented in FIG. 1 but their boiling points are representative of the functional boiling point ranges for formulation. Many other solvents and blends can be used to achieve good coating and imprinting including but not limited to cyclohexanone, 1,2 propanediol, N-methyl pyrrolidone, ethyl 3-ethoxypropionate, Dowanol, gamma butyrolactone, amyl acetate, 2-hepatanone, 4-methyl 2-pentanone, n-butyl acetate, and 4-methyl 2-pentanol.

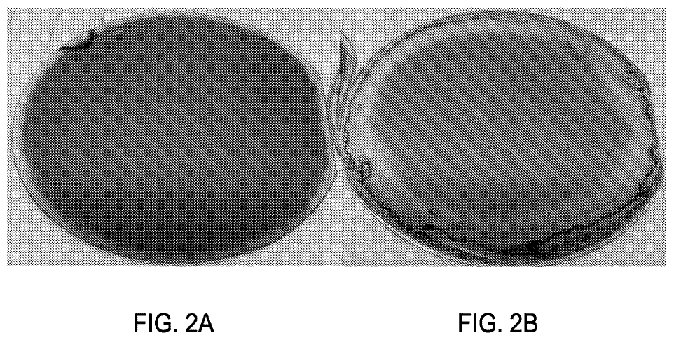

FIGS. 2A-B compare spin-coated films on 150 mm Si wafers from an ink including two low boiling solvents in FIG. 2B and an ink with additional heavy solvent, BEEA, in FIG. 2A, showing the scalability of the process to larger area substrates in the presence of the heavier solvent. The film on shown in FIG. 2A is cosmetically better with fewer point defects and smoother coating of the ink over a larger area to the edge of a 150 mm wafer. Hereafter, the solutions used to fabricate the films in FIGS. 2A and 2B are termed D1.1 (Pixelligent TiO₂, Nanocrystals 21 wt %, PGMEA 21 wt %, Ethyl Lactate 45.5 wt %, Capstone FS66 0.001 wt %, BEEA 7.5 wt %, and 3-(Trimethoxysilyl) propyl methacrylate 3.7 wt %) and V3.3 (Pixelligent TiO₂, Nanocrystals 21 wt %, PGMEA 21 wt %, Ethyl Lactate 54 wt %, Capstone FS66 0.001 wt %, and 3-(Trimethoxysilyl) propyl methacrylate 3.7 wt %), respectively. D1.1 utilizes a spinning condition of 2000 rpm, 1500 ramp rate, 30 seconds and affords a stable film after spin coating, giving a wide imprinting window of up to 4 minutes and V3.3 uses 4000 rpm, 1500 ramp rate, 3 seconds and provides a narrower imprint window of 20+/−5 seconds, insufficient for some tool designs that require a longer transfer time to a separate module for the next fabrication steps. Both can be cured with continuous UV (33V, 40 mJ/cm²) or pulsed UV (35 V, pulses of 5 ms on and 15 ms off with 2000 repetitions, 40 mJ/cm²) modes but the figures presented here are only cured by pulsed UV with a pulsed UV tool from Carpe Diem Technologies. The obvious difference is due to the optimization using a film stabilizing high boiling point solvent in engineered quantities to stabilize the film without affecting the required energy input to decompose the solvent and cure the imprint material. It has been found that increasing the UV dose was required for imprint materials containing high quantities of heavier solvent without which they unable to cure completely. Therefore, a balance between film stability and curability is necessary for the proper deposition and patterning of nanoparticle composites.

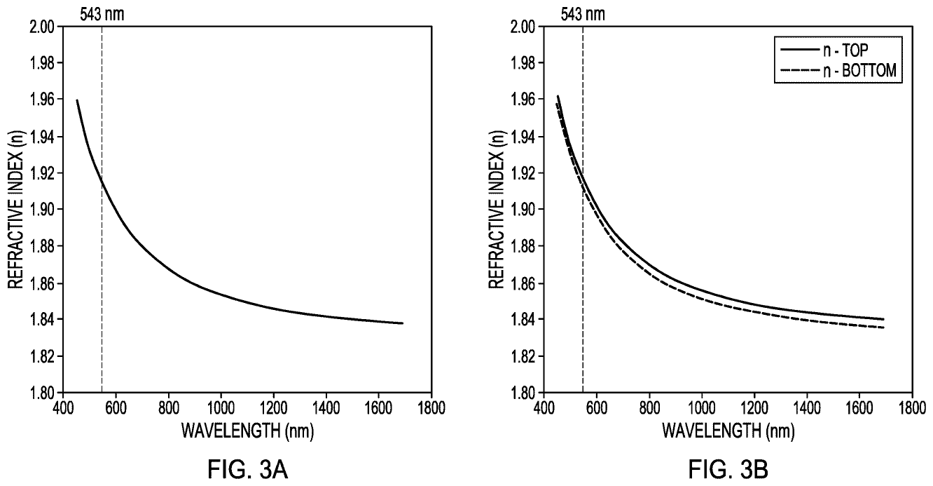

FIG. 3 shows the refractive index (RI) curves of spin-coated films prepared from D1.1 on a 150 mm Si wafer after 2,000 repetitions of pulsed UV over 40 seconds. The RI curve shown in FIG. 3A is fitted with the ideal Cauchy modelling function while that shown in FIG. 3B is with the graded function, which further takes into account the roughness and inhomogeneity of the film, providing two RI curves at the top and bottom of the film. The RIs calculated from the ideal and graded models at 543 nm are 1.916 and 1.918 (top)/1.914 (bottom), respectively, indicating the film is highly uniform without any significant gradient of RI throughout the film. The film thickness is about 590 nm.

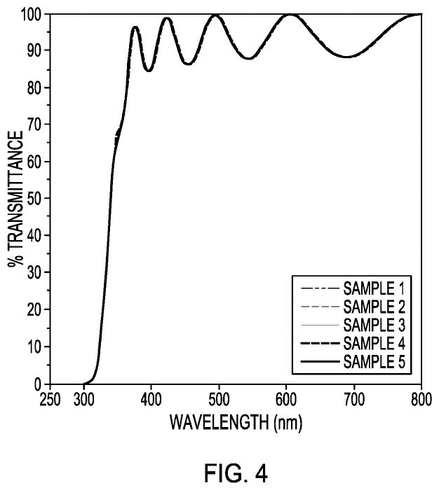

FIG. 4 shows the optical transmittance of the spin-coated films prepared from D1.1 on a 150 mm fused silica substrate after 2,000 repetitions of pulsed UV. Five different films are prepared to show the reproducibility of the data. The transmittance was normalized by a bare substrate. As shown in the figure, the films have high transmittance over the entire range of visible wavelengths from 400 to 800 nm. The ripples in these curves are due to the interference of the incident light and the reflected light at the interface between film and substrate. They are almost completely overlapped with one another. A very slight shift of the graph between samples is not indicative of film quality change but the result of slight change of conditions at the specific spot in each measurement. % Haze is also measured and calculated with the same UV-vis spectrometer (Perkin Elmer Lambda 1050) equipped with an integrating sphere. Table 1 lists % haze measured with these 5 films. As shown in the table, haze values are obtained at two specific wavelengths, 543 nm and 633 nm, together with the averaged value over the range of 400 to 800 nm to compensate the fluctuations of transmittance shown in FIG. 4. The % haze is calculated with the following equation using 4 different configurations (T1-T4) of measurement setup, % Haze=(T4/T2-T3/T1)×100, where T1 is a configuration closed with white standard at the exit of the integrating sphere, T3 is a configuration without the standard, T2 and T4 have the same configurations with T1 and T4, respectively, but the film is located at the entrance of the sphere. This equation eliminates a haze originating from the instrument itself by subtracting the term, T3/T1. In addition to this, we further ignore a haze caused by the substrate by subtracting the % haze of the bare substrate. After these subtraction procedures, all haze values listed in the table are lower than 1%, which verifies a negligible degree of scattering by the film itself.

TABLE 1
% Haze values of the film prepared from D1.1 at the
wavelengths of 543 and 633 nm and the values averaged
over the visible wavelength range of 400 to 800 nm

| | Averaged over | | |
|---|---|---|---|
| % Haze | 400-800 nm | @ 543 nm | @ 632 nm |
| Sample 1 | 0.24 | 0.49 | 0.06 |
| Sample 2 | 0.39 | 0.67 | 0.12 |
| Sample 3 | 0.25 | 0.49 | 0.04 |
| Sample 4 | 0.44 | 0.78 | 0.21 |
| Sample 5 | 0.33 | 0.65 | 0.13 |

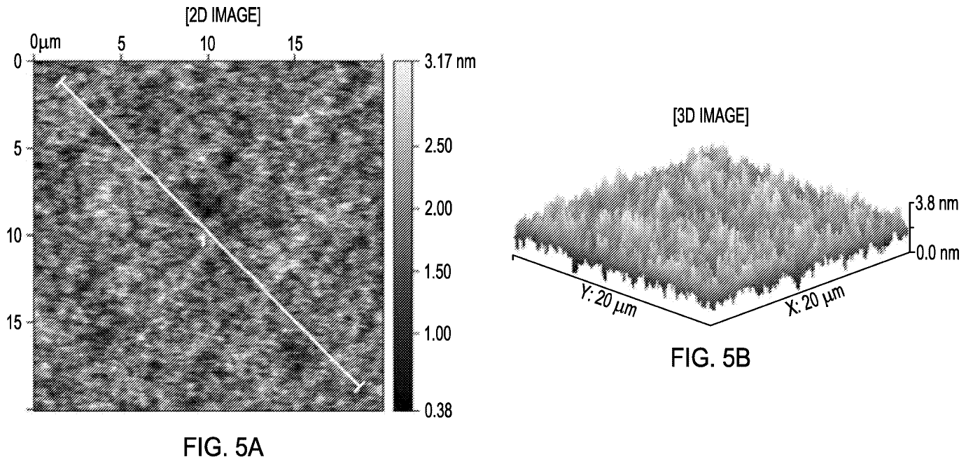

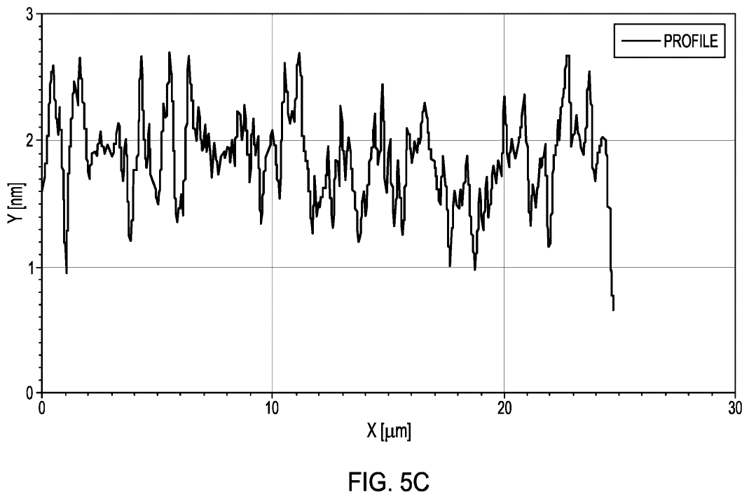

The film prepared from D1.1 formulation has excellent surface smoothness over a large area and its smoothness is characterized by atomic force microscopy (AFM). FIGS. 5A-C show the 2D (FIG. 5A) and 3D (FIG. 5B) AFM images of the film with the scanning area of 20 μm×20 μm and a height profile (FIG. 5C). The RMS roughness and Ra roughness in this area are calculated to be 0.439 and 0.348 nm, respectively.

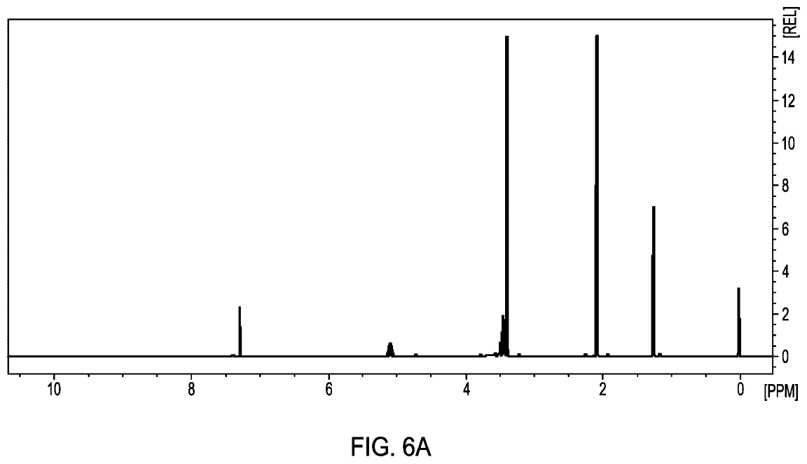

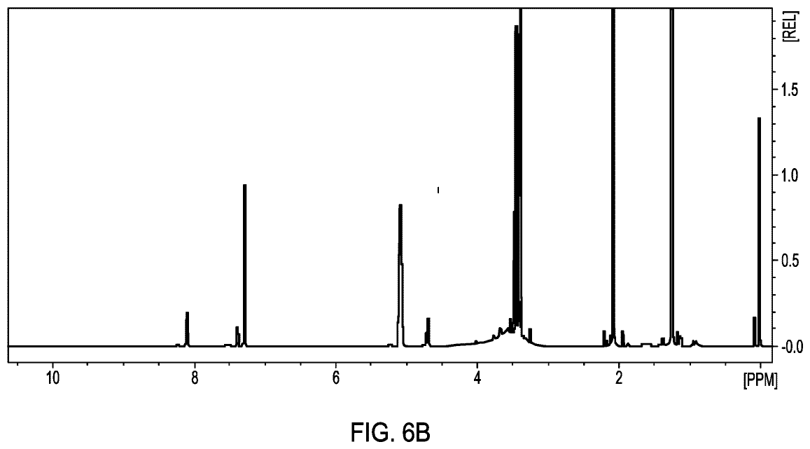

The curing mechanism and decomposition of the initial organic species are characterized by NMR for the solution state and IR for its solid spin-coated film on a Si wafer. To investigate the chemistry occurring in a solution between the nanoparticles, ligands and solvents, proton nuclear magnetic resonance (1H-NMR) spectra were taken on a solution formulated only with PGMEA without any other solvents or a binder before and after UV irradiation in a glass dish and can be seen in FIGS. 6A-B, with FIG. 6A being before UV irradiation and 6B being after UV irradiation. For this study, Pixelligent TiO₂ nanoparticles dispersed in PGMEA at the loading level of 50 wt %-were used as received. The cure conditions used were 35V, pulses of 5 ms on and 15 ms off, 15,000 repetitions, delivering an approximate dosage of 300 mJ/cm² over 5 minutes. As shown in FIG. 6A, NMR without UV irradiation presents a well resolved spectra containing carbonyl and ethylene peaks consistent with the solvent structure of PGMEA. Upon first assessment of FIG. 6B, it can be noticed with the UV-decomposed solution that well defined peaks in the aromatic, vinyl and trimethyl siloxane protected regions appear. These are some typical byproducts of photodegradation, local heating, or free radical chemistry. Additionally, the solvent peaks from PGMEA become broad and split into multiple small abundance side product peaks, indicating uncontrolled decomposition into species different from the original solvent. The smooth baseline and well refined peaks in the spectra indicate the peak broadening is not noise and confirms a mixture of the pristine and decomposed products after UV exposure. The UV exposed solution becomes a gel after being stored at ambient and dark condition after a week, which demonstrates that the ligands attached to the nanoparticles are partially or completely removed by UV as well, leading to the gelation of highly-loaded nanoparticle solution. The control, unexposed solution remains fluid after the same period of time.

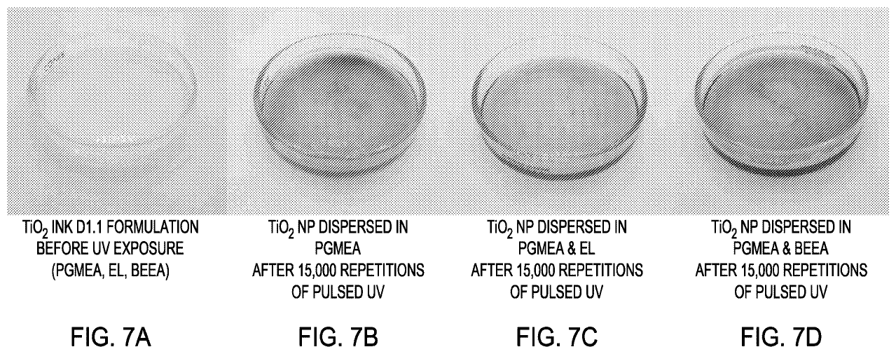

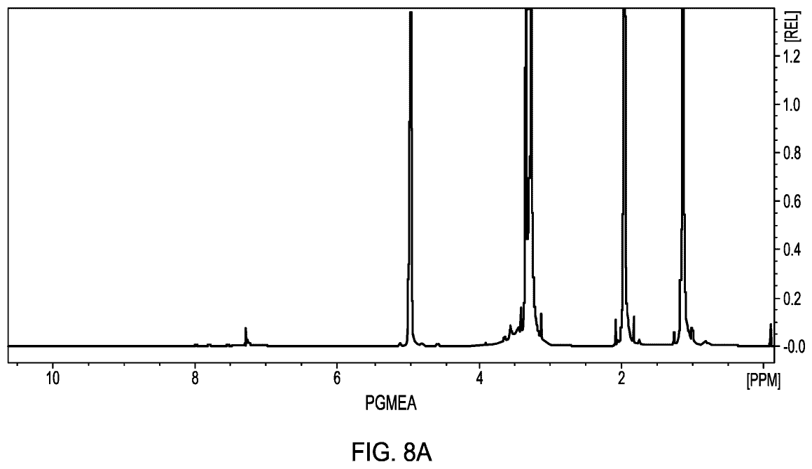

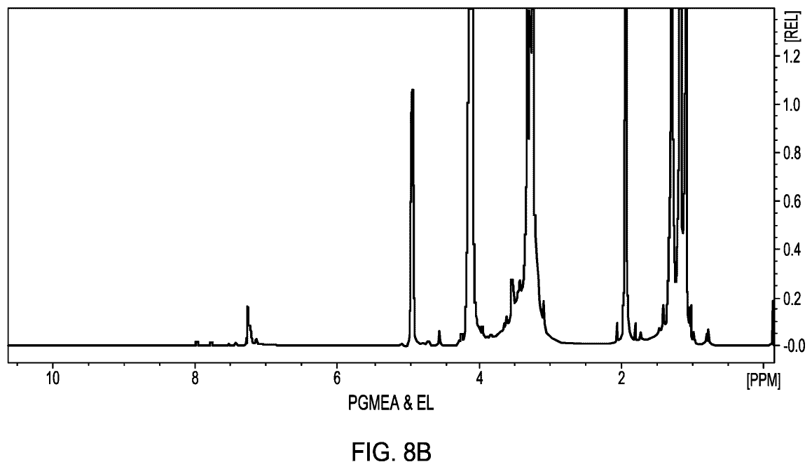

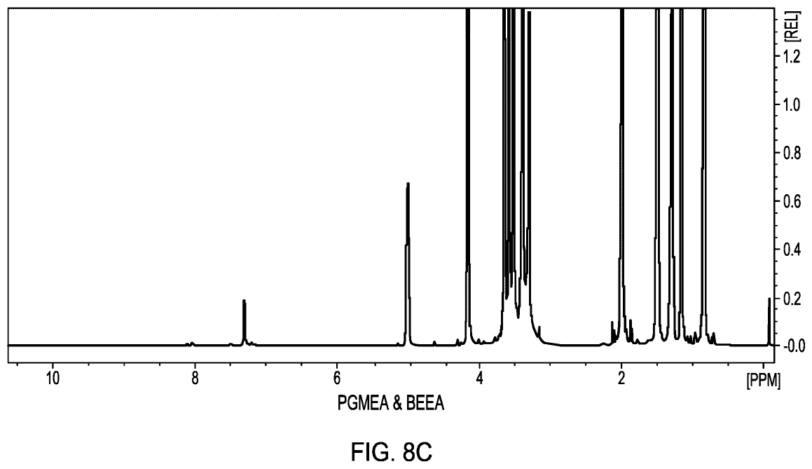

The UV-induced decomposition of other solvents in the presence of TiO₂ nanoparticles such as EL of low boiling point and BEEA of high boiling point is examined by NMR. The as-received TiO₂ ink from Pixelligent was diluted with one of the following solvents (PGMEA, EL, or BEEA) for NMR analysis, as shown in FIG. 7A. The photographs of these solutions after 15,000 repetitions of pulsed UV are shown in FIGS. 7B-D, with FIG. 7B showing PGMEA, FIG. 7C showing PGMEA and EL, and with FIG. 7D showing PGMEA and BEEA. Before UV curing, D1.1 formulation that contains all the three solvents, PGMEA, EL, and BEEA, is transparent and light yellow (FIG. 7A), whereas after 15,000 repetitions of pulsed UV, solutions turn dark yellow and opaque and generate some insoluble particles, irrespective of the composition of solvents (FIGS. 7B-7D). The three UV-decomposed solutions are analyzed by 1H-NMR. The solutions were filtered by a 5 μm PTFE syringe filter to eliminate any insoluble particles and then diluted with deuterated chloroform (CDCl₃). FIGS. 8A-C show the NMR spectra of the UV-cured solutions with three different solvent combinations of PGMEA, EL, and BEEA, with the solvent of FIG. 8A being PGMEA, the solvent of FIG. 8B being PGMEA and EL, and with the solvent of FIG. 8C being PGMEA and BEEA. The ink diluted only with PGMEA gives a similar profile compared to the NMR spectrum given in FIG. 6B as was expected. The NMR spectrum of the ink diluted with one of the low boiling solvents, EL, has some additional peaks around 4 ppm compared to the ink diluted only with PGMEA because it contains both PGMEA and EL. In a similar fashion, the ink diluted with one of the high boiling solvents, BEEA, also shows some additional signals around 1.5 ppm and 3.5 ppm. These additional peaks are due to the presence of secondary solvents, EL or BEEA, in addition to the primary solvent, PGMEA. In line with the NMR result shown in FIG. 6B, these solvent peaks originating from PGMEA, EL, and BEEA have multiple small abundance side product peaks next to the original peak from each pristine solvent, indicating uncontrolled decomposition into other species upon the exposure to high intensity UV source. The smooth baseline and well refined peaks in the spectra confirm the peak broadening and multiple side peaks are not noise and indicate a mixture of the pristine and decomposed products of each solvent or their combinations.

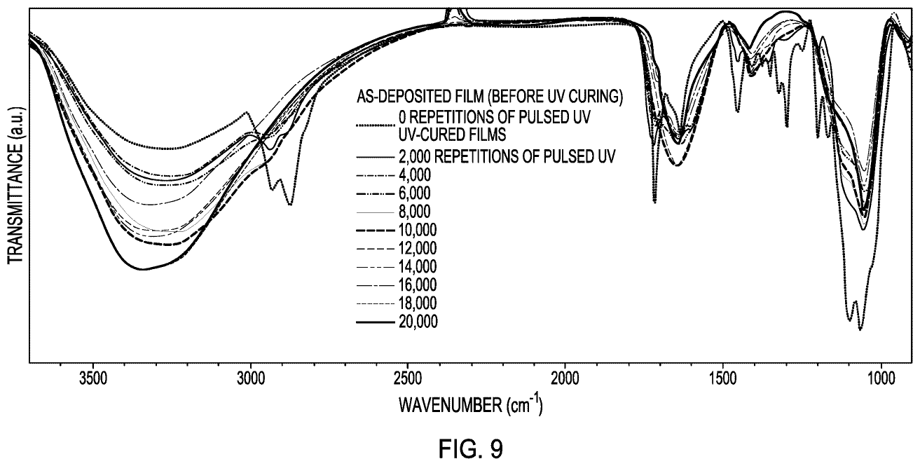

The decomposition process of organic moieties and the resultant conversion to an all-inorganic film under UV were investigated with planar spin coated films prepared from D1.1 formulation on 150 mm Si substrates. The IR spectra were obtained after various numbers of pulsed UV repetitions to track the disappearance of IR peaks from organics in terms of UV dosage. The film was scraped from the substrate and the collected solid powder was used for IR measurement. FIG. 9 shows that the as-deposited film before UV exposure (black line), have more IR signals compared to the UV-exposed films, indicating abundant organic moieties and functional groups originating from the solvents, ligand, and binder. After the UV curing process, however, there are some noticeable changes of peak intensities particularly around 2900, 1715, and 1100 cm⁻¹. Although it is difficult for these peaks to be assigned to the exact structures because of the complexity of the decomposition process and unknown ligand structure, these intensity changes are attributable to the disappearance of methylene —CH₂— linkage, conjugated ester group, and Si—O linkage, which are the key building blocks of the solvents, ligand and binder we used for D1.1. The organic content reduces significantly even after 2000 repetitions (red line), reconfirming the effective decomposition of organic species shown in the solution state with NMR. Further UV exposure sinters the inorganic structure as shown by the broad, symmetric titanol peak at 3300 cm⁻¹. Above 6000 repetitions (yellow line) almost all IR signals from organics disappear significantly and more specifically around 2900 and 1715 cm-1. The intensity of these peaks gets weaker drastically as UV dosage increases up to 20,000 repetitions (400 mJ/cm²). After 20,000 repetitions of pulsed UV, the signals from the solvents, ligand, and binder are negligibly detected by IR, suggesting the formation of an inorganic matrix between TiO₂ nanoparticles and supporting the destructive fashion of this work in making a structure. This IR result verifies the sintering and photooxidation activity of the titania nanoparticle composite, bringing about the successful transformation to an all-organic TiO₂-based film.

The detailed decomposition mechanism of the organic species under UV can be demonstrated by the two-dimensional correlation spectroscopy (2D-COS) of IR in terms of the number of UV pulses. By using 2D-COS, a sequence of spectral changes examined during the increase of UV dosage can be traced with the set of IR spectra given in FIG. 9.

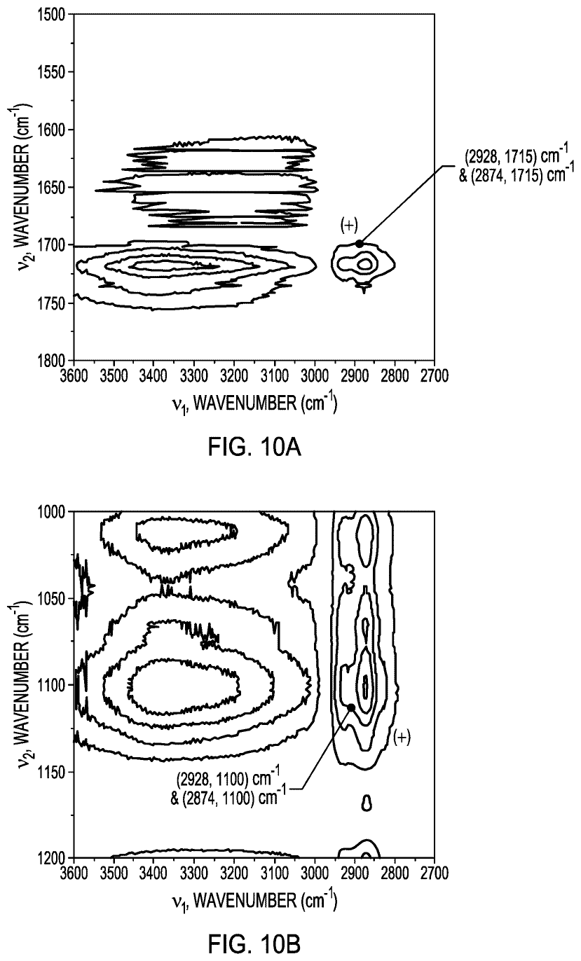

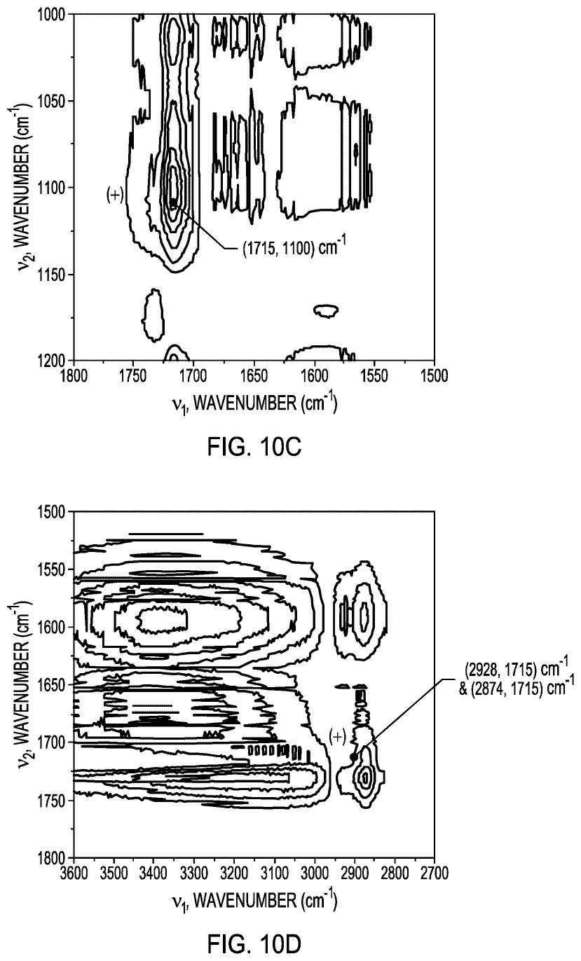

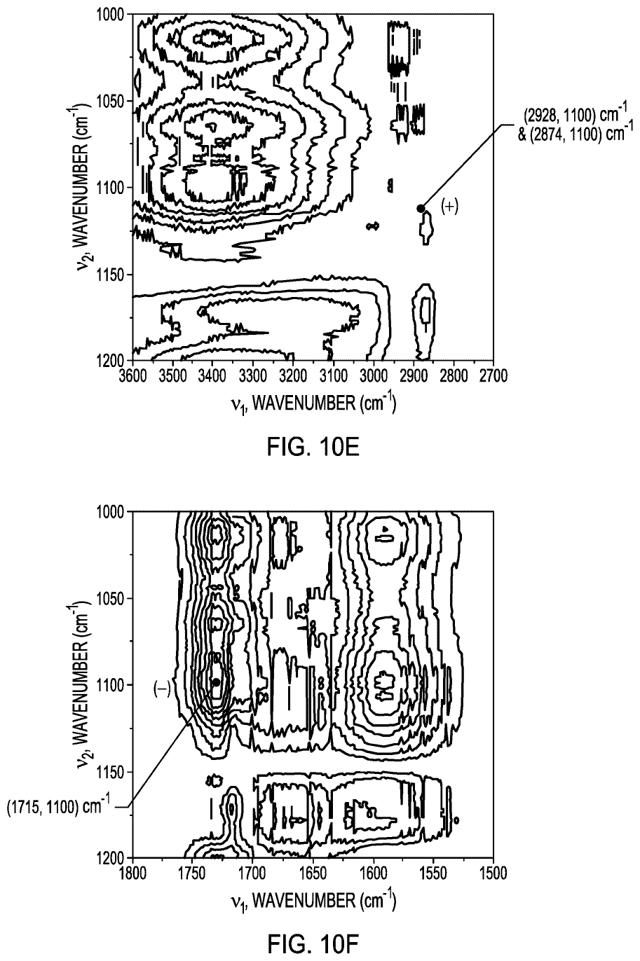

FIGS. 10A-F show the 2D correlation spectra in the regions of the IR bands that showed the noticeable change seen in the 1D spectra in FIGS. 6B and 8A-C such as the stretching bands of the methylene —CH₂— linkage (v(—CH₂—)) around 2900 cm⁻¹, carbonyl C═O group (v(C═O)) around 1715 cm⁻¹, and Si—O linkage (v(—Si—O—)) around 1100 cm⁻¹. As can be seen in the 1D spectra, the intensity of these peaks was all decreasing with increasing UV dosage, indicating they are decomposed by UV. From the hetero-region synchronous and asynchronous spectra of these bands, the order of the decomposition of the methylene —CH₂— linkage, carbonyl C—O group, and Si—O linkage can be revealed. In principle, if the signs of cross peaks (v₁, v₂) of these groups in synchronous and asynchronous are the same, the spectral intensity variation observed at v₁ occurs prior to that at v₂. If the signs are different, the sequence is reversed. For example, from the same positive (red) signs of the cross peaks at (2928, 1715) cm⁻¹ and (2874, 1715) cm⁻¹ in FIGS. 10A and 10D, the sequence between the methylene —CH₂— linkage (2928 and 2874 cm⁻¹) and carbonyl C—O group (1715 cm⁻¹) is given by 2928 & 2874 cm⁻¹→1715 cm⁻¹. On the basis of this principle, the same positive signs in FIGS. 10B and 10E indicates that the intensity change of —CH₂— occurs before that of Si—O, that is, 2928 & 2874 cm⁻¹→1100 cm⁻¹ whereas the opposite signs in FIGS. 10C and 10F reveals the sequence of 1100 cm⁻¹→1715 cm⁻¹. Overall, the entire sequence of the decomposition process of organic moieties in the films prepared from D1.1 is as follows: 2928 & 2874 cm⁻¹ (methylene —CH₂— linkage)→1100 cm⁻¹ (Si—O linkage)→1715 cm⁻¹ (carbonyl C═O group). From the 2D COS analysis, the decomposition mechanism and the resulting transformation mechanism to an all-inorganic film were further identified.

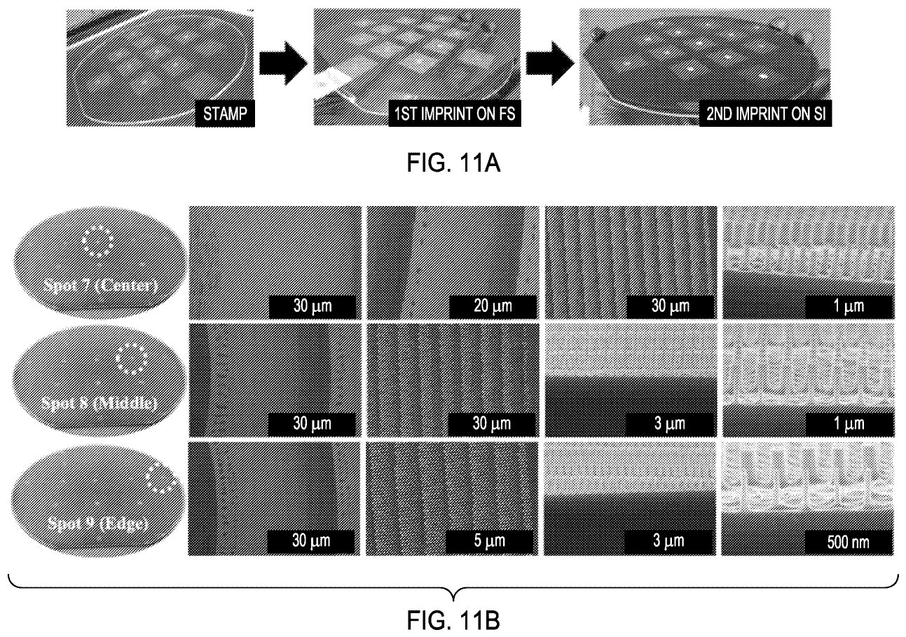

To demonstrate the imprintability of patterned structures accessible with the D1.1 formulation and process, FIG. 11A illustrates a method of forming a structured nanoparticle composite, with the left image showing elastomeric stamps that include hard and soft PDMS, the middle image showing the imprinting of the stamps on a spin-coated film of the D1.1 formulation on wafers, and with the right image showing the imprinted films on the wafers with the stamps removed. FIG. 11B illustrates optical images (the three left-most images) and corresponding scanning electron microscopy (SEM) images (the four images to the right of each optical image) of visible wavelength (543 nm) metalenses imprinted using a three-component solvent system (D1.1) with high and low boiling point solvents, proving high fidelity pattern replication on large wafers using extended processing times. The imprinted metalens patterns were replicated using an imprint mastering technique, not directly replicated from the original master mold. For this study, the D1.1 formulation and spin coating steps from before were used to deposit the film. The film was then laminated with an elastomeric stamp including hard and soft PDMS layers on a glass backing. After lamination, the pulsed UV source of 2000 repetitions, 35V, 5 ms on, 15 ms off was exposed through the stamp to the composite layer. After the UV cure, the stamp is peeled away from the surface to reveal the patterned nanoparticle composite. These features contain high aspect ratio (>8) and high refractive index features (n_{D} >1.9) including a plurality of nanoparticles, with a silane binder, surfactant, 2 low boiling point solvents and 1 high boiling point solvent. In fact, the 150 mm master used in this fabrication process also shows the stability and imprintability of D1.1 over an extended period after spin coating on a larger scale since the master was made with an imprint mastering technique. The 150 mm master including 13 lenses of 4 mm was made from the original single 4 mm master on a 1″×1″ coupon. 13 coupon-sized stamps were made individually from this master and these 13 stamps were placed down onto a spin-coated 150 mm film of D1.1 one by one. This whole lamination process of the 13 stamps took more than 4 minutes and the high fidelity nanopatterns achieved even from this imprint master reveals the extended imprinting window in the presence of the heavier BEEA solvent. This imprint master was used as a master through the surface modification with a fluorinating agent.

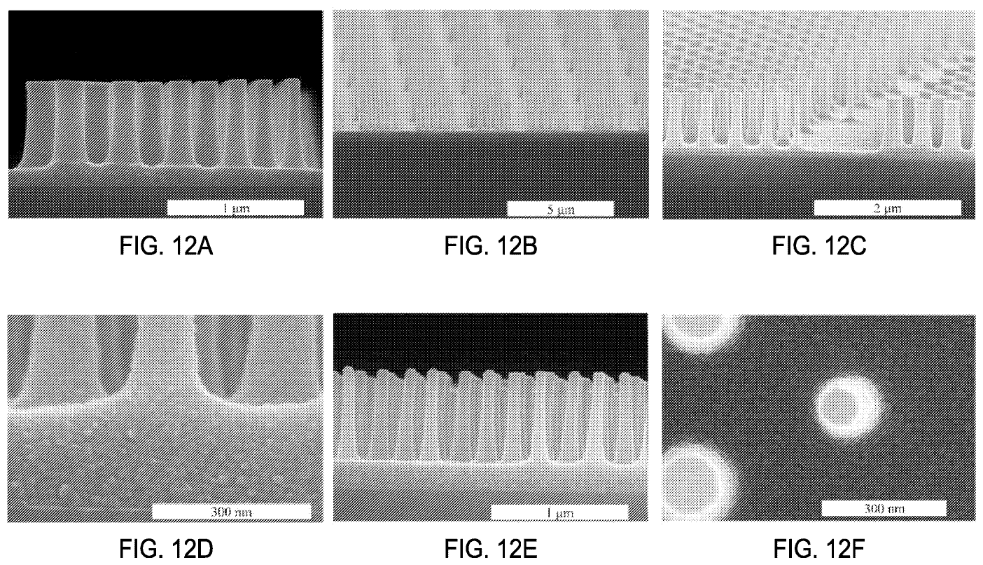

FIGS. 12A-F illustrate an imprinting result using another 4 mm metalens master. Unlike the SEM images shown in FIG. 11, the imprinted metalens structure shown in FIGS. 12A-F were replicated directly from the original 4 mm master mold within using the imprint mastering technique. FIGS. 12A-F illustrate SEM images of a visible wavelength (543 nm) metalens imprinted using a three-component solvent system (D1.1) with high and low boiling point solvents, with FIGS. 12A-B illustrating a TiO₂ particle size of 10 nm, and with FIGS. 12C-F illustrating a TiO₂ particle size of 20 nm. Regardless of the different particle sizes, the 4 mm metalens structure was successfully replicated from the master mold without observation of feature breakage.

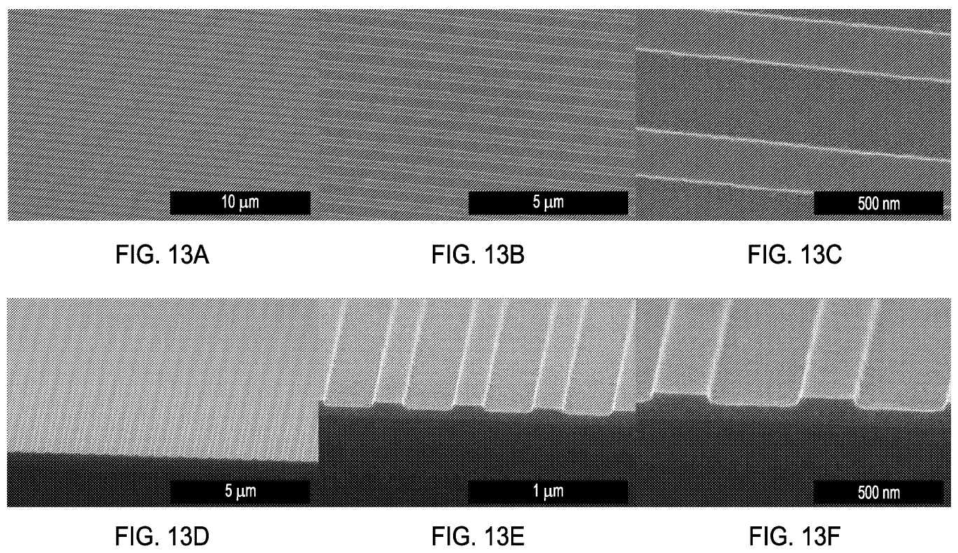

Optical gratings were fabricated using the same procedure as for FIG. 11 but using a template with visible pitch line patterns. FIGS. 13A-F show three different gratings with varying height, pitch and width demonstrating the successful large area patterning of line structures for optical gratings and waveguides in the visible spectrum.

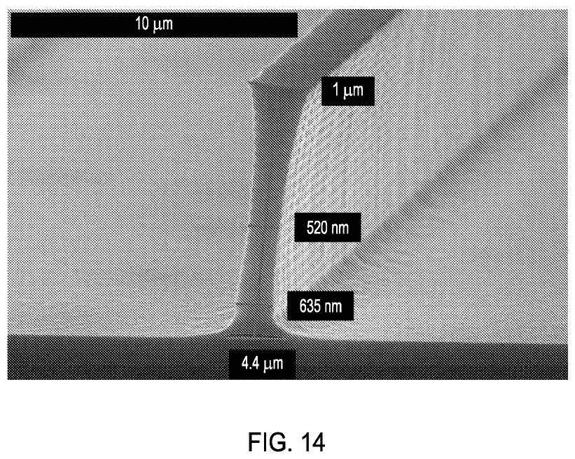

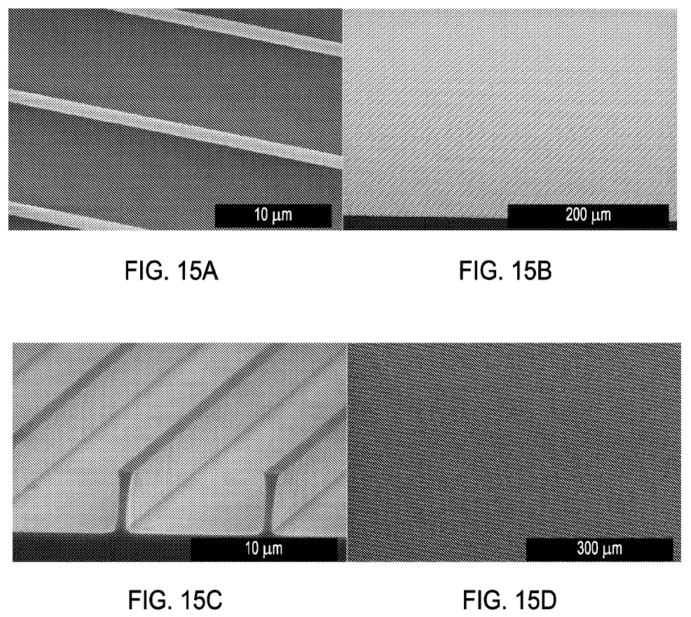

For the fabrication of IR metasurfaces, the pitch and feature height must be increased to match the increased wavelength for modulation. FIG. 14 shows an example structure fabricated using the D1.1 procedure used for FIGS. 11, 12A-F, and 13A-F. FIGS. 13A-F show an aspect ratio of 0.2 with a feature height of 40 nm and a width of 220 nm. The increased height and pitch enables a wide range of potential structures in the few micron regime to manipulate infrared light while maintaining the aspect ratios (>8) achieved at the nanoscale. FIGS. 15A-D illustrate SEM images showing the large area success of patterning IR scale nanoparticle composites with high consistency and an achieved maximum aspect ratio of 8.5 (4.4 μm height/520 nm width) and an average aspect ratio of 6.1 (4.4 μm height/0.72 μm width).

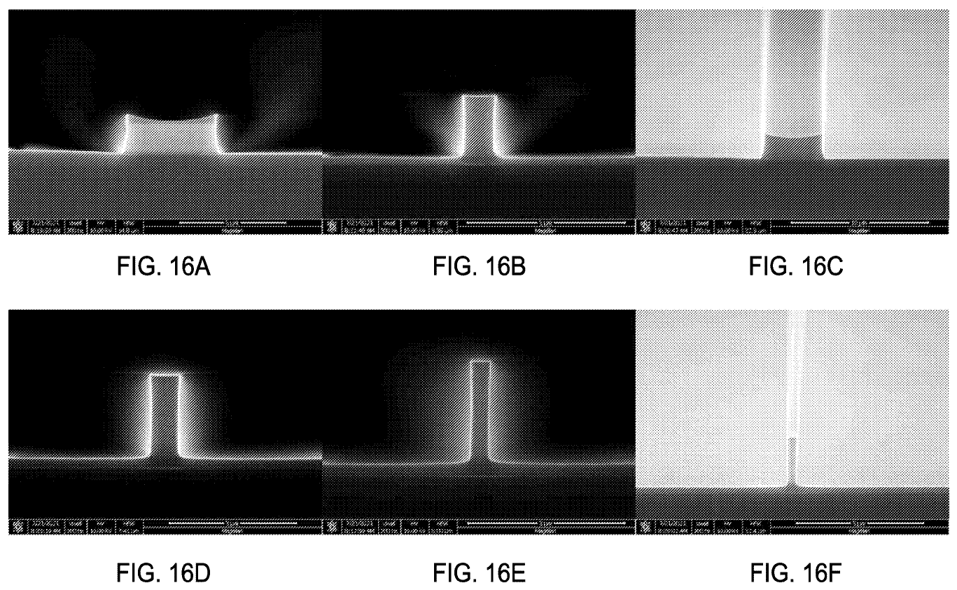

FIGS. 16A-F show the SEM images of imprints from D1.1 using the same process with another infrared wavelength waveguides with the optical gratings of different design. The pattern has various gratings with different aspect ratios and feature widths but the same heights. The biggest, the smallest, and medium-sized features are all shown in FIGS. 16A-F corresponding to aspect ratios of 0.4 (1.85 μm height/4.33 μm width), 1.8 (1.87 μm height/1.05 μm width) and 5 (1.87 μm height/0.37 μm width). These images also further confirm the imprintability of D1.1 over a wide range of feature sizes from nanometer (visible) to micrometer (IR) scales.

The terms and expressions that have been employed are used as terms of description and not of limitation, and there is no intention in the use of such terms and expressions of excluding any equivalents of the features shown and described or portions thereof, but it is recognized that various modifications are possible within the scope of the embodiments of the present invention. Thus, it should be understood that although the present invention has been specifically disclosed by specific embodiments and optional features, modification and variation of the concepts herein disclosed may be resorted to by those of ordinary skill in the art, and that such modifications and variations are considered to be within the scope of embodiments of the present invention.

### Exemplary Aspects.

The following exemplary aspects are provided, the numbering of which is not to be construed as designating levels of importance:

Aspect 1 provides a formulation for forming a structured nanoparticle composite, the formulation comprising:
nanoparticles with an average diameter of less than 50 nm;
a binder for the nanoparticles, wherein the binder acts as a solvent and/or dispersant for the nanoparticles and has a boiling point of 40° C. to 300° C.; and
optionally, at least one solvent with a boiling point of 40° C. to 300° C.

Aspect 2 provides the formulation of Aspect 1, wherein the formulation is free of solvents having a boiling point of 40° C. to 300° C. other than the binder.

Aspect 3 provides the formulation of Aspect 1, wherein the formulation comprises one or more solvents having a boiling point of 40° C. to 300° C. in addition to the binder.

Aspect 4 provides a formulation for forming a structured nanoparticle composite, the formulation comprising:
nanoparticles with an average diameter of less than 50 nm;
at least one solvent with a boiling point of 40° C. to 300° C.; and
a binder for the nanoparticles.

Aspect 5 provides the formulation of Aspect 4, wherein the binder for the nanoparticles has a different chemical structure than the at least one solvent with a boiling point of 40° C. to 300° C.

Aspect 6 provides the formulation of Aspect 4, wherein the binder for the nanoparticles is the at least one solvent with a boiling point of 40° C. to 300° C.

Aspect 7 provides the formulation of Aspect 4, wherein the binder for the nanoparticles acts as a solvent and/or dispersant for the nanoparticles and has a boiling point of 40° C. to 300° C., and the at least one solvent with a boiling point of 40° C. to 300° C. has a different chemical structure than the binder.

Aspect 8 provides the formulation of Aspect 1-7, wherein the nanoparticles comprise a metal oxide.

Aspect 9 provides the formulation of any one of Aspects 1-8, wherein the formulation includes ligands bound to the nanoparticles.

Aspect 10 provides the formulation of any one of Aspects 1-9, wherein the formulation includes functional groups bound the nanoparticles.

Aspect 11 provides the formulation of any one of Aspects 1-10, wherein the formulation contains a surfactant.

Aspect 12 provides the formulation of any one of Aspects 1-11, wherein the nanoparticles comprise TiO₂, ZrO₂, HfO₂, ZnO, or a combination thereof.

Aspect 13 provides the formulation of any one of Aspects 1-12, wherein the at least one solvent or the binder has a boiling point of 40° C. to 200° C.

Aspect 14 provides the formulation of any one of Aspects 1-13, wherein the at least one solvent or the binder comprises an ether functional group, an ester, acetate, ketone, methylene, ethylene, propylene, propylene oxide, ethylene oxide, methoxy, ethoxy, isopropoxy, hydroxyl, carboxylic acid, anhydride, urea, carbonate, silane, siloxane, acrylate, methacrylate, vinyl, hydride, phenyl, or a combination thereof.

Aspect 15 provides the formulation of any one of Aspects 1-14, wherein the at least one solvent or the binder comprises a solvent and/or binder with a boiling point of 100° C. to 200° C. and a solvent and/or binder with a boiling point of 170° C. to 300° C.

Aspect 16 provides the formulation of Aspect 15, wherein the solvent or binder with a boiling point of 100° C. to 200° C. comprises an ether functional group, an ester, acetate, ketone, methylene, ethylene, propylene, propylene oxide, ethylene oxide, methoxy, ethoxy, isopropoxy, hydroxyl, carboxylic acid, anhydride, urea, carbonate, silane, siloxane, acrylate, methacrylate, vinyl, hydride, phenyl, or a combination thereof.

Aspect 17 provides the formulation of any one of Aspects 15-16, wherein the solvent or binder with a boiling point of 100° C. to 200° C. is an ether, ester, acetate, ketone, methylene, ethylene, propylene, propylene oxide, ethylene oxide, methoxy, ethoxy, isopropoxy, hydroxyl, carboxylic acid, anhydride, urea, carbonate, silane, siloxane, acrylate, methacrylate, vinyl, hydride, phenyl, or a combination thereof.

Aspect 18 provides the formulation of any one of Aspects 15-17, wherein the solvent or binder with a boiling point of 100° C. to 200° C. is degradable by photooxidation.

Aspect 19 provides the formulation of any one of Aspects 15-18, wherein the solvent or binder with a boiling point of 170° C. to 300° C. comprises an ether functional group, an ester, acetate, ketone, methylene, ethylene, propylene, propylene oxide, ethylene oxide, methoxy, ethoxy, isopropoxy, hydroxyl, carboxylic acid, anhydride, urea, carbonate, silane, siloxane, acrylate, methacrylate, vinyl, hydride, phenyl, or a combination thereof.

Aspect 20 provides the formulation of any one of Aspects 15-19, wherein the solvent or binder with a boiling point of 170° C. to 300° C. is an ether, ester, acetate, ketone, methylene, ethylene, propylene, propylene oxide, ethylene oxide, methoxy, ethoxy, isopropoxy, hydroxyl, carboxylic acid, anhydride, urea, carbonate, silane, siloxane, acrylate, methacrylate, vinyl, hydride, phenyl, or a combination thereof.

Aspect 21 provides the formulation of any one of Aspects 1-20, wherein the solvent or binder with a boiling point of 170° C. to 300° C. is degradable by photooxidation.

Aspect 22 provides the formulation of any one of Aspects 1-21, wherein the nanoparticles are catalytic.

Aspect 23 provides the formulation of any one of Aspects 1-22, wherein the nanoparticles are photocatalytic.

Aspect 24 provides the formulation of any one of Aspects 15-23, wherein the nanoparticles are catalytic for photooxidation of the at least one solvent with a boiling point of 40° C. to 300° C. and/or of the binder.

Aspect 25 provides the formulation of any one of Aspects 15-24, wherein the nanoparticles are catalytic for photooxidation of the at least one solvent with a boiling point of 40° C. to 300° C. upon exposure to UV light and/or of the binder upon exposure to UV light.

Aspect 26 provides the formulation of any one of Aspects 15-25, wherein the nanoparticles are catalytic for photooxidation of the solvent with boiling point of 100° C. to 200° C. and/or of the binder.

Aspect 27 provides the formulation of any one of Aspects 15-26, wherein the nanoparticles are catalytic for photooxidation of the solvent with boiling point of 170° C. to 300° C. and/or of the binder.

Aspect 28 provides the formulation of any one of Aspects 15-27, wherein the nanoparticles are catalytic for photooxidation of the solvent with boiling point of 100° C. to 200° C. upon exposure to UV light and/or of the binder upon exposure to UV light.

Aspect 29 provides the formulation of any one of Aspects 15-28, wherein the nanoparticles are catalytic for photooxidation of the solvent with boiling point of 170° C. to 300° C. upon exposure to UV light and or of the binder upon exposure to UV light.

Aspect 30 provides the formulation of any one of Aspects 1-29, wherein the nanoparticles are catalytic for photooxidation of ligands bound to the surface of the nanoparticles.

Aspect 31 provides the formulation of any one of Aspects 1-30, wherein the nanoparticles are catalytic for photooxidation of the binder.

Aspect 32 provides the formulation of any one of Aspects 1-31, wherein the binder comprises a precursor of a material of the nanoparticles.

Aspect 33 provides the formulation of any one of Aspects 1-32, wherein the binder comprises a metal oxide precursor.

Aspect 34 provides the formulation of any one of Aspects 1-33, wherein the binder comprises an insulating material.

Aspect 35 provides the formulation of any one of Aspects 1-34, wherein the binder comprises a transparent optical adhesive.

Aspect 36 provides the formulation of any one of Aspects 1-35, wherein the binder is one of more of a monomer, alkoxide, oligomer, prepolymer, polymer, organic polymer, Si-containing polymer, caged polymer, branched polymer, silane coupling agent, silsesquioxanes, or a combination thereof.

Aspect 37 provides the formulation of any one of Aspects 1-36, wherein the binder comprises a silane coupling agent.

Aspect 38 provides a formulation for forming a structured nanoparticle composite, the formulation comprising:
photocatalytic nanoparticles with an average diameter of less than 50 nm;
a solvent with a boiling point of 40° C. to 200° C.; and
a binder for the nanoparticles that is a different compound than the solvent with a boiling point of 40° C. to 200° C., the binder comprising a precursor of a material of the nanoparticles, a metal oxide precursor, an insulating material, a transparent optical adhesive, a monomer, an alkoxide, an oligomer, a pre-polymer, a polymer, an organic polymer, a Si-containing polymer, a caged polymer, a branched polymer, a silane coupling agent, a silsesquioxane, or a combination thereof.

Aspect 39 provides a method of forming a structured nanoparticle composite, the method comprising:
disposing the formulation of any one of Aspects 1-38 on a substrate;
patterning the formulation disposed on the substrate to produce structures comprising at least one dimension that is less than 2 microns; and
photocatalytically oxidizing the patterned formulation to produce a patterned structure that is substantially free of organic material.

Aspect 40 provides the method of Aspect 39, wherein the photocatalytic oxidation degrades organic materials in the patterned formulation including but not limited to solvents, ligands bound to nanoparticles, binders, stabilizers, surfactants, or a combination thereof.

Aspect 41 provides the method of any one of Aspects 39-40, wherein the organic materials degraded in the patterned formulation comprise a solvent, ligand, a ligand bound to a nanoparticle, a binder, stabilizer, a surfactant, or a combination thereof.

Aspect 42 provides the method of any one of Aspects 39-41, wherein the photocatalytic oxidation comprises using UV light.

Aspect 43 provides the method of any one of Aspects 39-42, wherein the photocatalytic oxidation comprises using pulsed UV light.

Aspect 44 provides the method of any one of Aspects 39-43, wherein the photocatalytic oxidation comprises using UV light with a minimum intensity of 5 mW/cm².

Aspect 45 provides the method of any one of Aspects 39-44, wherein the photocatalytic oxidation comprises using UV light wherein each pulse has a minimum intensity of 5 mW/cm².

Aspect 46 provides the method of any one of Aspects 39-45, wherein the photocatalytic oxidation comprises using UV light with a wavelength of 365 nm.

Aspect 47 provides the method of any one of Aspects 39-46, wherein the photocatalytic oxidation comprises using light with a at least one wavelength of 100 to 450 nm.

Aspect 48 provides the method of any one of Aspects 39-47, wherein the photocatalytic oxidation comprises using pulsed UV light source using of 1000 to 20000 pulse repetitions.

Aspect 49 provides the method of any one of Aspects 39-48, wherein the photocatalytic oxidation comprises out using UV light generated using a light emitting diode.

Aspect 50 provides the method of any one of Aspects 39-49, wherein the photocatalytic oxidation comprises using light generated using a flash lamp.

Aspect 51 provides a structured nanoparticle composite prepared from the formulation of any one of Aspects 1-38 and/or prepared using the method of any one of Aspects 33-44.

Aspect 52 provides the structured nanoparticle composite of Aspect 51, wherein the structured nanoparticle composite is optically transparent at one or more wavelengths.

Aspect 53 provides the structured nanoparticle composite of any one of Aspects 51-52, wherein the structured nanoparticle composite comprises features with at least one dimension smaller than 1 micron.

Aspect 54 provides the structured nanoparticle composite of any one of Aspects 51-53, wherein the structured nanoparticle composite is arranged to manipulate electromagnetic radiation.

Aspect 55 provides the structured nanoparticle composite of any one of Aspects 51-54, wherein the structured nanoparticle composite is arranged to manipulate visible light.

Aspect 56 provides the structured nanoparticle composite of any one of Aspects 51-55, wherein the structured nanoparticle composite is arranged to manipulate infrared light.

Aspect 57 provides the structured nanoparticle composite of any one of Aspects 51-56, wherein the structured nanoparticle composite is an optical grating.

Aspect 58 provides the structured nanoparticle composite of any one of Aspects 51-57, wherein the structured nanoparticle composite is a metalens or holographic element.

Aspect 59 provides the structured nanoparticle composite of any one of Aspects 51-58, wherein the structured nanoparticle composite is a component of a 3D sensor.

Aspect 60 provides the formulation, method, or structured nanoparticle composite of any one or any combination of Aspects 1-59 optionally configured such that all elements or options recited are available to use or select from.

What is claimed is:

1. A formulation for forming a structured nanoparticle composite, the formulation comprising:
nanoparticles with an average diameter of less than 50 nm;
at least one solvent with a boiling point of 40° C. to 300° C.; and
a binder for the nanoparticles that has a different chemical structure than the at least one solvent with a boiling point of 40° C. to 300° C.

2. The formulation of claim 1, wherein the nanoparticles comprise a metal oxide.

3. The formulation of claim 1, wherein the formulation includes ligands bound to the nanoparticles.

4. The formulation of claim 1, wherein the formulation includes functional groups bound to the nanoparticles.

5. The formulation of claim 1, wherein the formulation contains a surfactant.

6. The formulation of claim 1, wherein the nanoparticles comprise TiO₂, ZrO₂, HfO₂, ZnO, or a combination thereof.

7. The formulation of claim 1, wherein the at least one solvent and/or the binder has a boiling point of 40° C. to 300° C.

8. The formulation of claim 1, wherein the at least one solvent and/or the binder comprises an ether functional group, an ester, acetate, ketone, methylene, ethylene, propylene, propylene oxide, ethylene oxide, methoxy, ethoxy, isopropoxy, hydroxyl, carboxylic acid, anhydride, urea, carbonate, silane, siloxane, acrylate, methacrylate, vinyl, hydride, phenyl, or a combination thereof.

9. The formulation of claim 1, wherein the at least one solvent comprises a solvent with a boiling point of 100° C. to 200° C. and a solvent with a boiling point of 170° C. to 300° C.

10. The formulation of claim 9, wherein the solvent with a boiling point of 100° C. to 200° C. and/or the solvent with a boiling point of 170° C. to 300° C. is degradable by photooxidation.

11. The formulation of claim 1, wherein the nanoparticles are catalytic for photooxidation of the at least one solvent with a boiling point of 100° C. to 200° C. and/or the solvent with a boiling point of 170° C. to 300° C. upon exposure to UV light.

12. The formulation of claim 1, wherein the binder comprises a precursor of a material of the nanoparticles, a metal oxide precursor, an insulating material, a transparent optical adhesive, a monomer, an alkoxide, an oligomer, a pre-polymer, a polymer, an organic polymer, a Si-containing polymer, a caged polymer, a branched polymer, a silane coupling agent, a silsesquioxane, or a combination thereof.

13. A formulation for forming a structured nanoparticle composite, the formulation comprising:
photocatalytic nanoparticles with an average diameter of less than 50 nm;
a solvent with a boiling point of 40° C. to 200° C.; and
a binder for the nanoparticles that has a different chemical structure than the solvent with a boiling point of 40° C. to 200° C., the binder comprising a precursor of a material of the nanoparticles, a metal oxide precursor, an insulating material, a transparent optical adhesive, a monomer, an alkoxide, an oligomer, a pre-polymer, a polymer, an organic polymer, a Si-containing polymer, a caged polymer, a branched polymer, a silane coupling agent, a silsesquioxane, or a combination thereof.

14. A method of forming a structured nanoparticle composite, the method comprising:
disposing the formulation of claim 1 on a substrate;
patterning the formulation disposed on the substrate to produce structures comprising at least one dimension that is less than 2 microns; and
photocatalytically oxidizing the patterned formulation to produce a patterned structure that is substantially free of organic material.

15. The method of claim 14, wherein the photocatalytic oxidation comprises using UV light.

16. The method of claim 14, wherein the photocatalytic oxidation comprises using UV light with a minimum intensity of 5 mW/cm².

17. A structured nanoparticle composite prepared from the formulation of claim 1.

18. The structured nanoparticle composite of claim 17, wherein the structured nanoparticle composite is optically transparent at one or more wavelengths.

19. The structured nanoparticle composition of claim 17, wherein the structured nanoparticle composite is a metalens, a holographic element, a component of a 3D sensor, an optical grating, or a combination thereof.

20. A formulation for forming a structured nanoparticle composite, the formulation comprising:
nanoparticles with an average diameter of less than 50 nm; and
a binder for the nanoparticles, wherein the binder acts as a solvent and/or dispersant for the nanoparticles and has a boiling point of 40° C. to 300° C.
